(19) United States
(12) Patent Application Publication
(10) Pub. No.: US 2025/0248047 A1
(43) Pub. Date: Jul. 31, 2025

(54) VARIABLE RESISTANCE MEMORY DEVICE

(71) Applicant: SAMSUNG ELECTRONICS CO., LTD., SUWON-SI (KR)

(72) Inventor: Hyungjong Jeong, Suwon-si (KR)

(21) Appl. No.: 19/023,671

(22) Filed: Jan. 16, 2025

(30) Foreign Application Priority Data
Jan. 26, 2024 (KR) 10-2024-0012667

(51) Int. Cl. H10B 61/00

(52) U.S. Cl. CPC H10B 61/10

(57) ABSTRACT

A variable resistance memory device includes a substrate that includes a first region and a second region, a plurality of variable resistance pattern structures that respectively constitute a plurality of memory cells in the first region, capping layer patterns that cover sidewalls of the plurality of variable resistance pattern structures, an inter-wiring insulating layer in the second region, buried layer patterns that cover the capping layer patterns in the first region, a first insulating stopper layer that covers upper surfaces of the capping layer patterns, a second insulating stopper layer that covers a part of an upper surface of the inter-wiring insulating layer in the second region, and an insulating cover layer that covers an upper surface of the first insulating stopper layer, an upper surface of the second insulating stopper layer, and the upper surface of the inter-wiring insulating layer.

### CROSS-REFERENCE TO RELATED APPLICATION

This application claims priority under 35 U.S.C. § 119 from Korean Patent Application No. 10-2024-0012667, filed on Jan. 26, 2024 in the Korean Intellectual Property Office, the contents of which are herein incorporated by reference in their entirety.

### TECHNICAL FIELD

Embodiments of the inventive concept are directed to a variable resistance memory device, and more particularly, to a variable resistance memory device with increased reliability.

### DISCUSSION OF THE RELATED ART

Memory devices used in semiconductor products need increased operating speeds and increased integration. Variable resistance memory devices have been proposed to satisfy such requirements. Variable resistance memory devices use current transfer characteristics of a variable resistance layer according to an applied voltage. A representative example of variable resistance memory devices is a magnetoresistive random-access memory (MRAM).

An embedded magnetic random access memory (eMRAM) device has a cell array region and a peripheral circuit region, and a plurality of variable resistance pattern structures that constitute a plurality of memory cells are disposed in the cell array region. When forming metal wires in the peripheral circuit region at the same level as the plurality of variable resistance pattern structures, a planarization process is performed to pattern the metal wires to be formed on the upper side.

However, when performing a planarization process such as a CMP process, a step may occur between the cell array region and the peripheral circuit region due to the difference in a removal rate and/or a pattern density, and thus, a photolithography process that selectively performs an etching process is used.

### SUMMARY

Embodiments of the inventive concept provide a variable resistance memory device having increased reliability.

According to an embodiment of the inventive concept, there is provided a variable resistance memory device that includes a substrate that includes a first region and a second region, a plurality of variable resistance pattern structures disposed in the first region and that respectively constitute a plurality of memory cells and that are spaced apart from each other in a horizontal direction, capping layer patterns that cover sidewalls of the plurality of variable resistance pattern structures, an inter-wiring insulating layer disposed in the second region and that includes at least a part located at a same vertical level as the plurality of variable resistance pattern structures, buried layer patterns disposed in the first region and that cover the capping layer patterns and fill a part of lower portions of spaces between the plurality of variable resistance pattern structures, a first insulating stopper layer that fills a part of upper portions of the spaces between the plurality of variable resistance pattern structures and covers upper surfaces of the capping layer patterns, a second insulating stopper layer disposed in the second region and that covers a part of an upper surface of the inter-wiring insulating layer and is spaced apart from the first insulating stopper layer in the horizontal direction, and an insulating cover layer that covers an upper surface of the first insulating stopper layer, an upper surface of the second insulating stopper layer, and the upper surface of the inter-wiring insulating layer.

According to another embodiment of the inventive concept, there is provided a variable resistance memory device that includes a substrate that includes a first region and a second region, a plurality of variable resistance pattern structures disposed in the first region and that respectively constitute a plurality of memory cells and are spaced apart from each other in a horizontal direction, capping layer patterns that cover sidewalls of the plurality of variable resistance pattern structures, buried layer patterns disposed in the first region and that cover the capping layer patterns and fill a part of lower portions of spaces between the plurality of variable resistance pattern structures, an inter-wiring insulating layer disposed in the second region and that includes at least a part located at a same vertical level as the plurality of variable resistance pattern structures and includes an insulating material with a lower dielectric constant than each of the buried layer patterns, and an insulating stopper structure that fills a part of upper portions of the spaces between the plurality of variable resistance pattern structures and covers the capping layer patterns, the inter-wiring insulating layer, and the plurality of variable resistance patterns. The insulating stopper structure includes an insulating stopper recess located in a portion of the second region adjacent to the first region, extends from a lower surface of the insulating stopper structure to an inside of the insulating stopper structure, and is filled by a portion of the inter-wiring insulating layer.

According to another embodiment of the inventive concept, there is provided a variable resistance memory device that includes a substrate that includes a cell array region and a peripheral circuit region, an isolation insulating layer disposed in the cell array region and the peripheral circuit region, a plurality of variable resistance pattern structures disposed on the isolation insulating layer in the cell array region, where the plurality of variable resistance pattern structures constitute a plurality of memory cells and are spaced apart from each other in a horizontal direction, capping layer patterns that cover sidewalls of the plurality of variable resistance pattern structures and an upper surface of the isolation insulating layer, buried layer patterns disposed in the cell array region and that cover the capping layer patterns and fill a part of lower portions of spaces between the plurality of variable resistance pattern structures, an inter-wiring insulating layer disposed on the isolation insulating layer in the peripheral circuit region, where the inter-wiring insulating layer includes at least a part located at a same vertical level as the plurality of variable resistance pattern structures and includes an insulating material with a lower dielectric constant than each of the buried layer patterns, an insulating stopper structure that covers the capping layer patterns, the inter-wiring insulating layer, and the plurality of variable resistance patterns, and includes an insulating material that has a higher dielectric constant than silicon oxide but a lower dielectric constant than silicon nitride, a bit line disposed in the cell array region and that penetrates the insulating stopper structure and extends in contact with upper surfaces of the plurality of variable resistance pattern structures, and a wiring line and a wiring contact surrounded by the inter-wiring insulating layer and that are disposed in the peripheral circuit region. The insulating stopper structure includes a first insulating stopper layer that fills a part of upper portions of the spaces between the plurality of variable resistance pattern structures and covers upper surfaces of the capping layer patterns in the cell array region, a second insulating stopper layer that covers a part of an upper surface of the inter-wiring insulating layer and that is spaced apart from the first insulating stopper layer in the horizontal direction in the peripheral circuit region, an insulating cover layer that covers an upper surface of the first insulating stopper layer, an upper surface of the second insulating stopper layer, and the upper surface of the inter-wiring insulating layer, and an insulating stopper recess defined by the first insulating stopper layer, the second insulating stopper layer, and the insulating cover layer, and that is filled by a portion of the inter-wiring insulating layer. A horizontal width of the insulating stopper recess in the horizontal direction is about 1 times to about 2 times a thickness of the inter-wiring insulating layer.

### BRIEF DESCRIPTION OF THE DRAWINGS

FIG. 1 is a circuit diagram of a cell array of a variable resistance memory device according to an embodiment.

FIG. 2 is a circuit diagram of a magnetoresistive memory cell of FIG. 1.

FIG. 3 is a perspective view of a magnetoresistive memory cell of FIG. 2.

FIGS. 4 and 5 illustrate a write operation of a magnetic tunnel junction (MTJ) layer of a magnetoresistive memory cell of FIG. 1.

FIGS. 6A to 6E illustrate various embodiments of MTJ layers of a magnetoresistive memory cell of FIG. 1.

FIGS. 7A and 7B are plan views of a variable resistance memory device according to an embodiment.

FIGS. 8A and 8B are cross sectional views of a variable resistance memory device according to an embodiment.

FIGS. 9A and 9B are cross sectional views of a variable resistance memory device according to an embodiment.

FIGS. 10 to 17 are cross-sectional views that illustrate a method of manufacturing a variable resistance memory device according to an embodiment.

FIG. 18 is a block diagram of a variable resistance memory device according to an embodiment.

FIG. 19 is a block diagram of a data processing system that includes a variable resistance memory device according to an embodiment.

FIG. 20 is a block diagram of a data processing system that includes a variable resistance memory device according to an embodiment.

### DETAILED DESCRIPTION

In this specification, when a first component is described as contacting a second component, the first component is in direct contact with the second component.

The term “about” as used herein is inclusive of the stated value and means within an acceptable range of deviation for the particular value as determined by one of ordinary skill in the art, considering the measurement in question and the error associated with measurement of the particular quantity, such as the limitations of the measurement system. For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art.

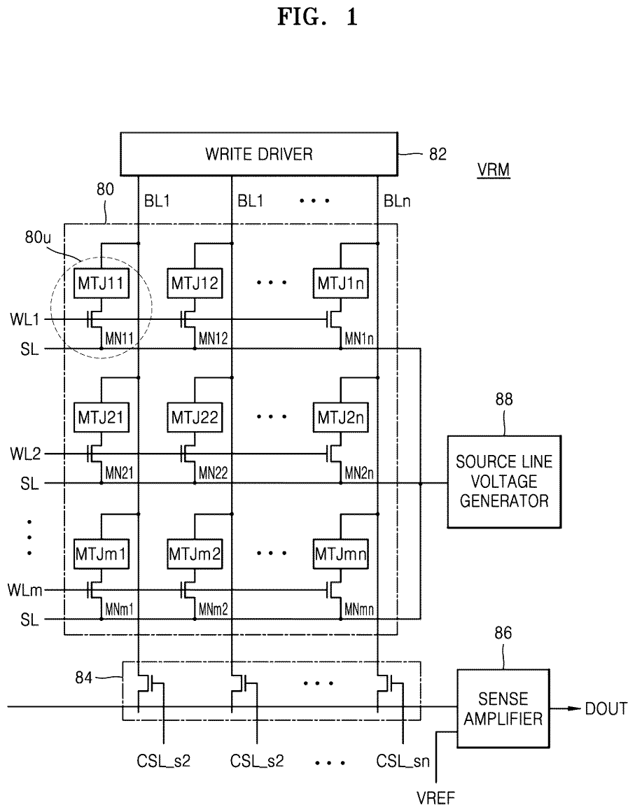

FIG. 1 is a circuit diagram of a cell array of a variable resistance memory device VRM according to an embodiment.

Referring to FIG. 1, in an embodiment, the variable resistance memory device VRAM includes a magnetoresistive memory cell array 80. The magnetoresistive memory cell array 80 may be referred to as a memory cell array. The magnetoresistive memory cell array 80 is connected to a write driver 82, a selection circuit 84, a source line voltage generator 88, and a sense amplifier 86. The magnetoresistive memory cell array 80 includes a plurality of magnetoresistive memory cells 80u. The magnetoresistive memory cell 80u may be referred to as a memory cell. The magnetoresistive memory cell array 80 includes a plurality of word lines WL1 to WLm and a plurality of bit lines BL1 to BLn. The magnetoresistive memory cell array 80 includes the magnetoresistive memory cells 80u respectively between the word lines WL1 to WLm and the bit lines BL1 to BLn.

In some embodiments, the variable resistance memory device VRAM is a magnetoresistive memory device. The magnetoresistive memory device is magnetoresistive random-access memory (MRAM). A variable resistance memory device VRM includes a variable resistance layer. For example, the variable resistance layer is a magnetic tunnel junction (MTJ) layer.

The magnetoresistive memory cell array 80 includes cell transistors MN11 to MNmn that have gates respectively connected to the word lines WL1 to WLm, and magnetic tunnel junction (MJT) layers MTJ11 to MTJmn that are respectively connected between the cell transistors MN11 to MNmn and the bit lines BL1 to BLn and constitute a variable resistance layer.

The respective sources of the cell transistors MN11 to MNIn are coupled to a source line SL. The selection circuit 84 selectively connects the bit lines BL1 to BLn to the sense amplifier 86 in response to column selection signals CSL_s1 to CSL_sn. The sense amplifier 86 amplifies a difference between an output voltage signal of the selection circuit 84 and a reference voltage VREF to generate output data DOUT.

The write driver 82 is connected to the bit lines BL1 to BLn, generates a program current based on write data, and provides the program current to the bit lines BL1 to BLn. To magnetize the MTJ layers MTJ11 to MTJmn in the magnetoresistive memory cell array 80, a voltage higher than a voltage applied to the bit lines BL1 to BLn is applied to the source line SL. The source line voltage generator 88 generates a source line driving voltage and provides the source line driving voltage to source lines SL of the magnetoresistive memory cell array 80.

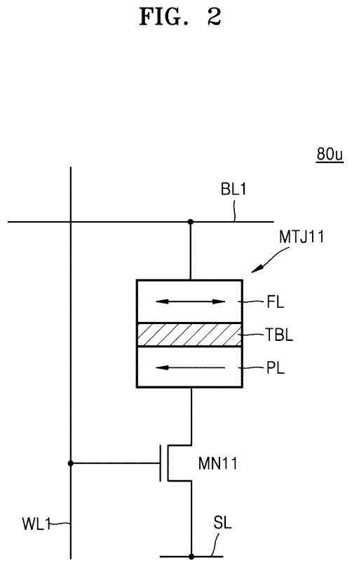

FIG. 2 is a circuit diagram of the magnetoresistive memory cell 80u of FIG. 1.

Referring to FIG. 2, in an embodiment, the magnetoresistive memory cell 80u includes the cell transistor MN11 configured as an NMOS transistor and the MTJ layer MTJ11. The cell transistor MN11 has a gate connected to the word line WL1 and a source connected to the source line SL. The MTJ layer MTJ11 is connected between a drain of the cell transistor MN11 and the bit line BL1.

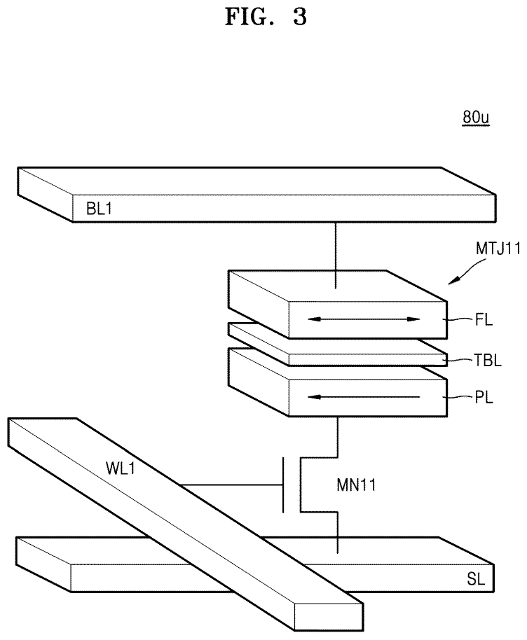

FIG. 3 is a perspective view of the magnetoresistive memory cell 80u of FIG. 2.

Referring to FIG. 3, in an embodiment, the MTJ layer MTJ11 includes a pinned layer PL that has a pinned or fixed magnetization direction, a free layer FL magnetized in the direction of an externally applied magnetic field, and a tunnel barrier layer TBL formed as an insulator layer between the pinned layer PL and the free layer FL.

The MTJ layer MTJ11 is included in a cell that constitutes a spin-transfer torque magnetoresistive random-access memory (STT-MRAM). To perform a write operation on the STT-MRAM, a logic high voltage is applied to the word line WL1 to turn on the cell transistor MN11, and a write current flows between the bit line BL1 and the source line SL.

To perform a read operation on the STT-MRAM, a logic high voltage is applied to the word line WL1 to turn on the cell transistor MN11, and a read current is applied from the bit line BL1 to the source line SL to determine data stored in the magnetoresistive memory cell 80u according to a resistance value of the MTJ layer MTJ11 with respect to the read current.

The resistance value of the MTJ layer MTJ11 varies depending on the magnetization direction of the free layer FL. For example, the magnetization direction of the free layer FL and the magnetization direction of the pinned layer PL are parallel in the MTJ layer MTJ11. For example, the MTJ layer MTJ11 has a low resistance value and reads data ‘0’. For example, the magnetization direction of the free layer FL is antiparallel to the degradation direction of the pinned layer PL. For example, the MTJ layer MTJ11 has a high resistance value and reads data ‘1’.

FIGS. 2 and 3 show embodiments in which the magnetoresistive memory cell 80u is a horizontal magnetic device in which the magnetization direction of the free layer FL and the magnetization direction of the pinned layer PL are horizontal, but embodiments are not necessarily limited thereto. In other embodiments, as described below, the magnetoresistive memory cell 80u is a vertical magnetic device in which the magnetization direction of the free layer FL and the magnetization direction of the pinned layer PL are vertical.

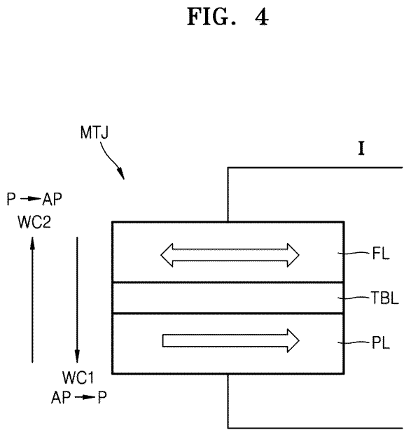

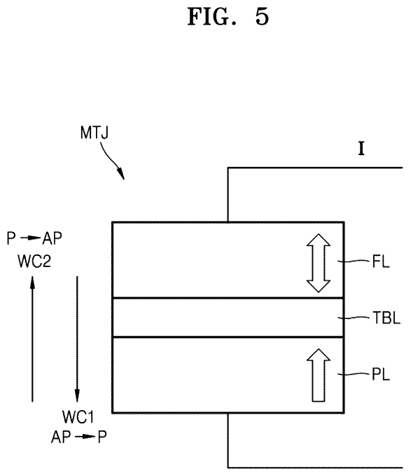

FIGS. 4 and 5 illustrate a write operation of an MTJ layer of a magnetoresistive memory cell of FIG. 1.

Referring to FIG. 4, in an embodiment, the MTJ layer is configured as a horizontal magnetic device in which the magnetization direction of the free layer FL and the magnetization direction of the pinned layer PL are horizontal. The MTJ layer in which the magnetization directions are horizontal is a case in which a moving direction of current and an easy axis of magnetization are substantially vertical.

Referring to FIG. 5, in an embodiment, the MTJ layer is configured as a vertical magnetic device in which the magnetization direction of the free layer FL and the magnetization direction of the pinned layer PL are vertical. The MTJ layer in which the magnetization directions are vertical is a case in which the moving direction of current and the easy axis of magnetization are substantially horizontal.

Referring to FIGS. 4 and 5, in embodiments, the magnetization direction of the free layer FL is determined according to write currents WC1 and WC2 that flow through the MTJ layer. For example, when the first write current WC1 is applied, free electrons that have the same spin direction as the pinned layer PL apply torque to the free layer FL. Accordingly, the free layer FL is magnetized parallel P to the pinned layer PL.

When the second write current WC2 is applied, electrons that have a spin opposite to that of the pinned layer PL return to the free layer FL and apply torque. Accordingly, the free layer FL is magnetized antiparallel AP to the pinned layer PL. For example, the magnetization direction of the free layer FL in the MTJ layer is changed by a spin transfer torque (STT).

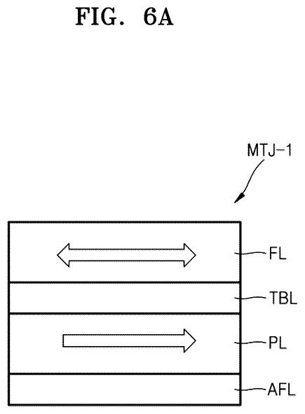

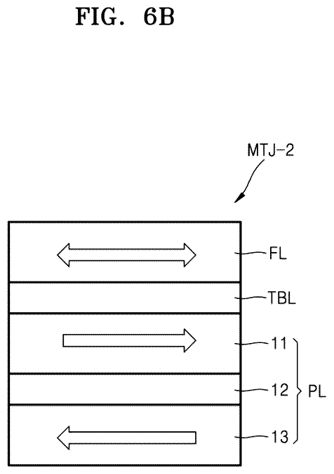

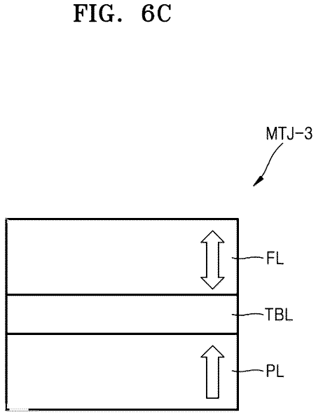

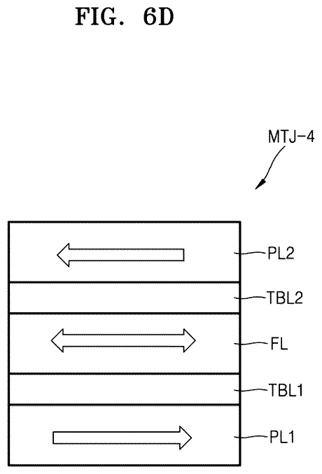

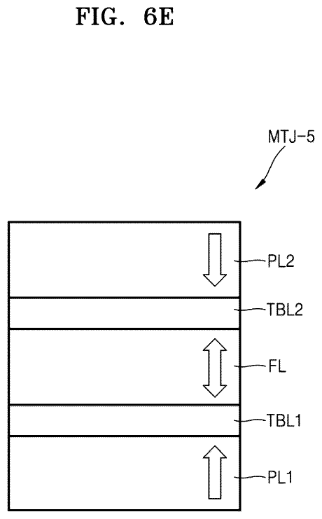

FIGS. 6A to 6E illustrating embodiments of MTJ layers MTJ-1 to MTJ-5 of a magnetoresistive memory cell of FIG. 1.

Referring to FIG. 6A, in an embodiment, the MTJ layer MTJ-1 includes the free layer FL, the tunnel barrier layer TBL, the pinned layer PL, and an antiferromagnetic layer AFL. The MTJ layer MTJ-1 is a single MTJ layer. The MTJ layer MTJ-1 configures a horizontal magnetic device in which the magnetization direction of the free layer FL and the magnetization direction of the pinned layer PL are horizontal. In some embodiments, the MTJ layer MTJ-1 includes the free layer FL, the tunnel barrier layer TBL, the pinned layer PL but may not include the antiferromagnetic layer AFL.

The free layer FL includes a material that has a changeable magnetization direction. The magnetization direction of the free layer FL can be changed by electrical/magnetic factors outside and/or inside the magnetoresistive memory cell. The free layer FL includes a ferromagnetic material that includes at least one of cobalt (Co), iron (Fe), or nickel (Ni). For example, the free layer FL includes at least one of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂.

The tunnel barrier layer TBL has a thickness that is less than a spin diffusion distance. The tunnel barrier layer TBL includes a non-magnetic material. For example, the tunnel barrier layer TBL includes at least one oxide of magnesium (Mg), titanium (Ti), aluminum (Al), magnesium-zinc (MgZn) or magnesium-boron (MgB), or a nitride of titanium (Ti) or vanadium (V).

The pinned layer PL has a pinned or fixed magnetization direction. In some embodiments, the pinned layer PL has a magnetization direction pinned or fixed by the antiferromagnetic layer AFL. In addition, the pinned layer PL includes a ferromagnetic material. For example, the pinned layer PL includes at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂.

The antiferromagnetic layer AFL includes an antiferromagnetic material. For example, the antiferromagnetic layer AFL includes at least one of PtMn, IrMn, MnO, MnS, MnTe, MnF₂, FeCl₂, FeO, CoCl₂, CoO, NiCl₂, NiO, or Cr.

Referring to FIG. 6B, in an embodiment, the MTJ layer MTJ-2 includes the free layer FL, the tunnel barrier layer TBL, and the pinned layer PL. The MTJ layer MTJ-2 configures a horizontal magnetic device in which the magnetization direction of the free layer FL and the magnetization direction of the pinned layer PL are horizontal. The pinned layer PL is a synthetic antiferromagnetic material (SAF). The pinned layer PL includes a first ferromagnetic layer 11, a bonding layer 12, and a second ferromagnetic layer 13. Each of the first ferromagnetic layer 11 and the second ferromagnetic layer 13 includes at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁. The magnetization direction of the first ferromagnetic layer 11 and the magnetization direction of the second ferromagnetic layer 13 differ from each other. The magnetization direction of the first ferromagnetic layer 11 and the magnetization direction of the second ferromagnetic layer 13 are pinned. The bonding layer 12 includes ruthenium (Ru).

Referring to FIG. 6C, in an embodiment, the MTJ layer MTJ-3 includes the free layer FL, the tunnel barrier layer TBL, and the pinned layer PL. The MTJ layer MTJ-3 is a single MTJ layer. The MTJ layer MTJ-3 configures a vertical magnetic device in which the magnetization direction of the free layer FL and the magnetization direction of the pinned layer PL are vertical. To implement the MTJ layer MTJ-3 that has a vertical magnetization direction, the free layer FL and the pinned layer PL each include a material that has a high magnetic anisotropy energy. For example, the free layer FL and the pinned layer PL each include a material that has a high magnetic anisotropy energy, such as an amorphous rare earth element alloy or a multilayer thin film such as (Co/Pt) n or (Fe/Pt) n.

For example, the free layer FL is an ordered alloy and includes at least one of iron (Fe), cobalt (Co), nickel (Ni), palladium (Pa), or platinum (Pt). For example, the free layer FL includes at least one of a Fe—Pt alloy, a Fep13 Pd alloy, a Co—Pd alloy, a Co—Pt alloy, a Fe—Ni—Pt alloy, a Co—Fe—Pt alloy, or a Co—Ni—Pt alloy. The alloy in the free layer FL is, for example, at least one of Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀ in a chemical quantitative expression.

The pinned layer PL is an ordered alloy, and includes at least one of iron (Fe), cobalt (Co), nickel (Ni), palladium (Pa), or platinum (Pt). For example, the pinned layer PL includes at least one of a Fe—Pt alloy, a Fe—Pd alloy, a Co—Pd alloy, a Co—Pt alloy, a Co—Fe—Pt alloy, or a Co—Ni—Pt alloy. The alloy in the pinned layer PL is, for example, at least one of Fe₅₀Pt₅₀, Fe₅₀Pd₅₀, Co₅₀Pd_{50,}Co₅₀Pt₅₀, Fe₃₀Ni₂₀Pt₅₀, Co₃₀Fe₂₀Pt₅₀, or Co₃₀Ni₂₀Pt₅₀ in the chemical quantitative expression.

Referring to FIG. 6D, in an embodiment, the MTJ layer MTJ-4 includes a first pinned layer PL1, a first tunnel barrier layer TBL1, the free layer FL, a second tunnel barrier layer TBL2, and a second pinned layer PL2. The MTJ layer MTJ-4 is a dual MTJ layer. The MTJ layer MTJ-4 configures a horizontal magnetic device in which a magnetization direction of the first pinned layer PL1, the magnetization direction of the free layer FL, and a magnetization direction of the second pinned layer PL2 are horizontal. The MTJ layer MTJ-4 has a structure in which the first tunnel barrier layer TBL1 and the first pinned layer PLI are sequentially disposed at one end of the free layer FL, and the second tunnel barrier layer TBL2 and the second pinned layer PL2 are sequentially disposed at the other end of the free layer FL. A material of the free layer FL, materials of the first pinned layer PL1 and the second pinned layer PL2, and materials of the first tunnel barrier layer TBL1 and the second tunnel barrier layer TBL2 are respectively the same as or similar to those of the free layer FL, the pinned layer PL, and the tunnel barrier layer TBL of FIG. 6A.

When the magnetization direction of the first pinned layer PL1 and the magnetization direction of the second pinned layer PL2 are pinned in opposite directions, magnetic forces of the first pinned layer PL1 and the second pinned layer PL2 are substantially offset. Therefore, the MTJ layer MTJ-4 can perform a write operation by using a current less than that of the MTJ layer MTJ-1 of FIG. 6A. In addition, due to the second tunnel barrier layer TBL2, the dual MTJ layer MTJ-4 provides higher resistance during a read operation, and thus, clear data values can be obtained.

Referring to FIG. 6E, in an embodiment, the MTJ layer MTJ-5 includes the first pinned layer PL1, the first tunnel barrier layer TBL1, the free layer FL, the second tunnel barrier layer TBL2, and the second pinned layer PL2. The MTJ layer MTJ-5 is a dual MTJ layer. The MTJ layer MTJ-5 configures a vertical magnetic device in which the magnetization direction of the first pinned layer PL1, the magnetization direction of the free layer FL, and the magnetization direction of the second pinned layer PL2 are vertical. The MTJ layer MTJ-5 has a structure in which the first tunnel barrier layer TBL1 and the first pinned layer PLI are sequentially disposed at one end of the free layer FL, and the second tunnel barrier layer TBL2 and the second pinned layer PL2 are sequentially disposed at the other end of the free layer FL. A material of the free layer FL, materials of the first pinned layer PLI and the second pinned layer PL2, and materials of the first tunnel barrier layer TBL1 and the second tunnel barrier layer TBL2 are respectively the same as or similar to those of the free layer FL, the pinned layer PL, and the tunnel barrier layer TBL of FIG. 6C.

When the magnetization direction of the first pinned layer PL1 and the magnetization direction of the second pinned layer PL2 are pinned in opposite directions, magnetic forces of the first pinned layer PLI and the second pinned layer PL2 are substantially offset. Therefore, the MTJ layer MTJ-5 can perform a write operation by using a current less than that of the MTJ layer MTJ-3 of FIG. 6C.

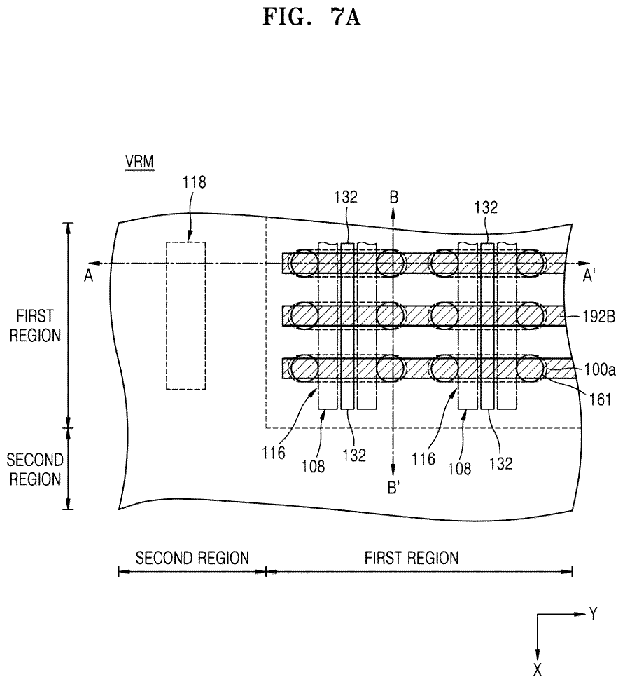

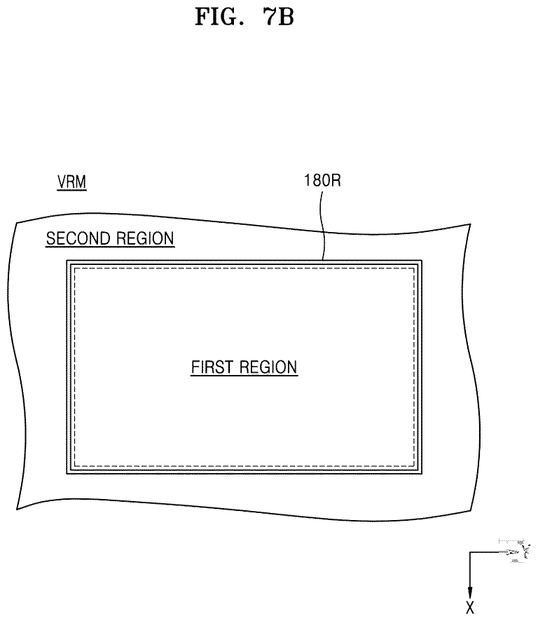

FIGS. 7A and 7B are plan views of a variable resistance memory device VRM according to an embodiment.

Referring to FIGS. 7A and 7B together, in an embodiment, the variable resistance memory device VRM is a magnetoresistive memory device. The variable resistance memory device VRM includes a first region and a second region. The first region is a cell array region that includes memory cells, such as magnetoresistive memory cells. The second region is located in the periphery of the first region, and is a peripheral circuit region that includes core/peripheral circuits.

The first region includes active regions 100a that have an isolated island shape and are regularly arranged in a first direction (X direction) and a second direction (Y direction). Two first transistors 116 are provided in each of the active regions 100a.

For example, the two first transistors 116 include two first gate electrodes 108 and are formed in each of the active regions 100a. The first gate electrodes 108 have a linear shape that extends in the first direction (X direction).

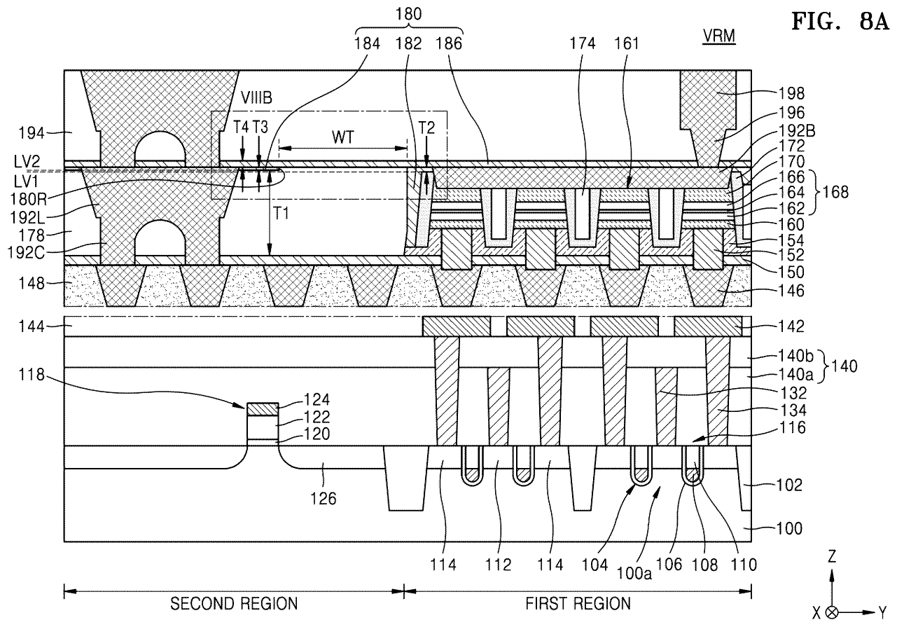

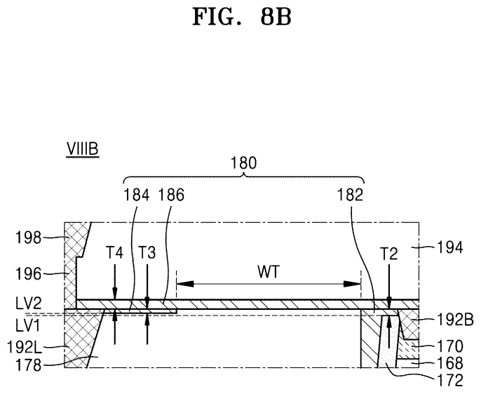

A central part of each of the active regions 100a includes a source line 132 that extends and contacts a first source region 112 (see FIG. 8A). The source line 132 extends in a first horizontal direction (X direction). First drain regions (114 in FIG. 8A) are located at both edge sides of each of the active regions 100a.

A variable resistance pattern structure 161 that constitutes a memory cell is disposed on the first drain regions (114 in FIG. 8A) at both edge sides of each of the active regions 100a. The variable resistance pattern structure 161 has an isolated island shape and is regularly arranged in the first horizontal direction (X direction) and a second horizontal direction (Y direction).

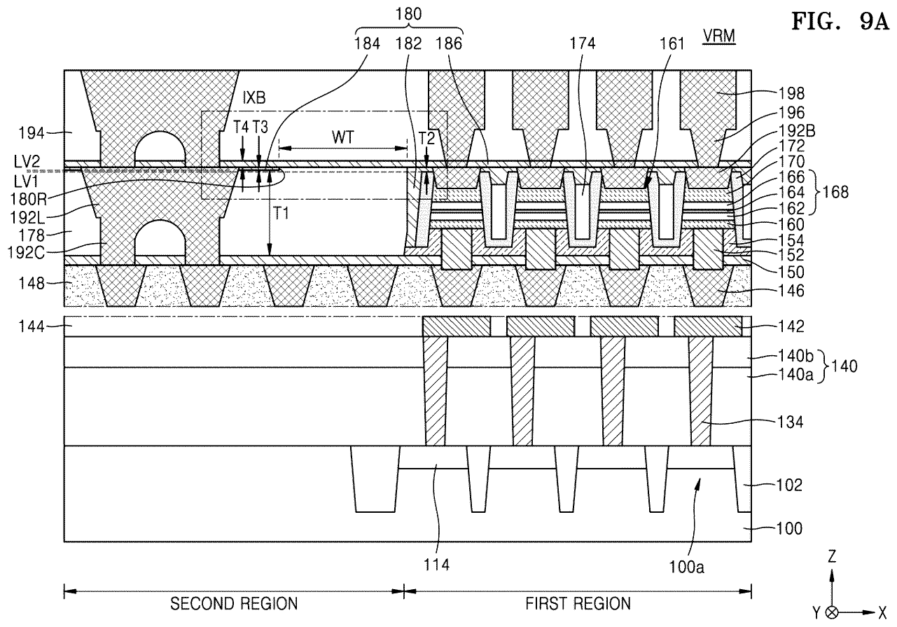

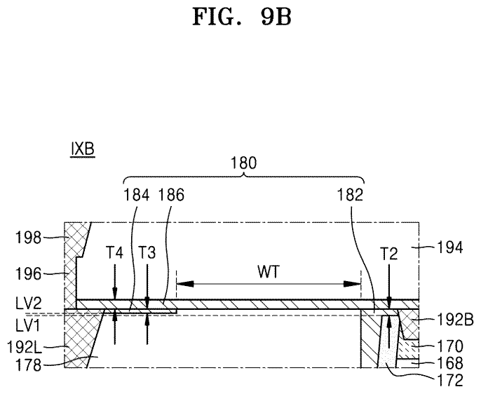

The variable resistance pattern structure 161 includes a variable resistance layer. For example, the variable resistance pattern structure 161 includes the MJT layers MTJ11 to MTJmn, MTJ, MTJ-1, MTJ-2, MTJ-3, MTJ-4, and MTJ-5 shown in FIGS. 1 to 6E or an MJT pattern 168 shown in FIGS. 8A and 9A. As described below, the variable resistance pattern structure 161 has a structure in which a lower electrode (160 in FIGS. 8A and 9A), an MJT pattern (168 in FIGS. 8A and 9A), and an upper electrode (170 in FIGS. 8A and 9A) are stacked.

A bit line 192B that extends while contacting an upper surface of the variable resistance pattern structure 161 is disposed on the variable resistance pattern structure 161. The bit line 192B extend in the second horizontal direction (Y direction) perpendicular to the first horizontal direction (X direction). A plurality of bit lines 192B extend parallel to each other in the second horizontal direction (Y direction).

The second region includes a second transistor 118 that includes core/peripheral circuits. The second transistor 118 includes a second gate insulating layer pattern (120 in FIG. 8A), a second gate electrode (122 in FIG. 8A), and a second source/drain region (126 in FIG. 8A) as described below.

In some embodiments, the second region completely surrounds the first region in plan view. An insulating stopper recess 180R is located in a portion of the second region adjacent to the first region and surrounds the first region. For example, the insulating stopper recess 180R extends along the edge of the first region in the first horizontal direction (X direction) and the second horizontal direction (Y direction) and completely surrounds the first region. The insulating stopper recess 180R will be described in detail with reference to FIGS. 8A to 9B.

FIGS. 8A and 8B are cross-sectional views of the variable resistance memory device VRM according to an embodiment. For example, FIG. 8A is a cross-sectional view taken along line A-A′ of FIG. 7A, FIG. 8B is an enlarged view of portion VIIIB of FIG. 8A, FIG. 9A is a cross-sectional view taken along line B-B′ of FIG. 7, and FIG. 9B is an enlarged view of portion IXB of FIG. 9A.

Referring to FIGS. 8A to 9B together, in an embodiment, the variable resistance memory device VRM includes a substrate 100 divided into a first region and a second region. The first region is a cell array region that includes magnetoresistive memory cells. The second region is a peripheral circuit region located in the periphery of the first region and that includes core/peripheral circuits. In some embodiments, the second region completely surrounds the first region in a plan view, as shown in FIG. 7B. In the first region and the second region, the substrate 100 includes an active region 100a defined by a device isolation layer 102.

A first transistor 116 is provided in the active region 100a of the first region. For example, two first transistors 116 that include two first gate electrodes 108 are formed in the active region 100a. The first source region 112 is formed in a central part of the active region 100a. The first source region 112 is a common source region shared by the two first transistors 116 formed in the active region 100a. First drain regions 114 are formed at both edge sides of the active region 100a.

In some embodiments, the first transistor 116 is a buried gate type transistor. The first gate electrode 108 is located inside a trench 104 formed in the substrate 100. The first gate electrode 108 fills a lower part of the trench 104. A first gate insulating layer pattern 106 is disposed between the substrate 100 and the first gate electrode 108. A first hard mask pattern 110 covers the first gate electrode 108 and fills an upper part of the trench 104. The first gate insulating layer pattern 106, the first gate electrode 108, and the first hard mask pattern 110 may together be referred to as a first gate structure. In some embodiments, the first transistor 116 is a planar type transistor in which the first gate electrode 108 is formed on an upper surface of the substrate 100.

A source line 132 is formed on the first source region 112 of the active region 100a. The source line 132 contacts an upper surface of the first source region 112. The source line 132 includes at least one of a metal such as tungsten, titanium, or tantalum, etc., or a metal nitride such as tungsten nitride, titanium nitride, or tantalum nitride, etc.

The second transistor 118 that includes core/peripheral circuits is formed on the substrate 100 in the second region. In some embodiments, the second transistor 118 is a planar type transistor. For example, the second transistor 118 includes a second gate insulating layer pattern 120, a second gate electrode 122, and a second source/drain region 126 formed on the substrate 100 in the second region. A second hard mask pattern 124 covers the second gate electrode 122. The second gate insulating layer pattern 120, the second gate electrode 122, and the second hard mask pattern 124 may together be referred to as a second gate structure.

A first interlayer insulating layer 140 is formed on the substrate 100 in the first region and the second region. The first interlayer insulating layer 140 covers the source line 132, the first transistor 116, and the second transistor 118 with sufficient thicknesses. In some embodiments, the first interlayer insulating layer 140 includes a first lower interlayer insulating layer 140a and a second lower interlayer insulating layer 140b. The source line 132 penetrates the first lower interlayer insulating layer 140a.

A contact plug 134 that penetrates the first interlayer insulating layer 140 and contacts the first drain region 114 is formed in the first region. The contact plug 134 penetrates the first lower interlayer insulating layer 140a and the second lower interlayer insulating layer 140b and contacts the first drain region 114. An upper surface of the contact plug 134 is located at a higher vertical level than an upper surface of the source line 132.

A first wiring line 142 is disposed on the contact plug 134. A first inter-wiring insulating layer 144 is disposed between the first wiring lines 142. The first inter-wiring insulating layer 144 surrounds the first wiring lines 142. The first inter-wiring insulating layer 144 includes silicon oxide or an insulating material with a lower dielectric constant than silicon oxide. For example, the first inter-wiring insulating layer 144 includes at least one of a tetraethyl orthosilicate (TEOS) film, an ultra low K (ULK) film, or an extreme low-K (ELK) film. In some embodiments, the ULK film or the ELK layer have a dielectric constant of about 2 to about 3.5. In some embodiments, the first inter-wiring insulating layer 144 includes at least one of a SiOC film, a SiOF film, a SiCH film, a SiCOH film, or a combination thereof.

First wiring contacts 146 are disposed on the first wiring lines 142. The first wiring contacts 146 are electrically connected to corresponding first wiring lines 142. In some embodiments, the first wiring contacts 146 contact the corresponding first wiring lines 142, but embodiments are not necessarily limited thereto. For example, at least one wiring contact and at least one wiring line are disposed between each pair of corresponding first wiring lines 142 and first wiring contacts 146, so that each of the corresponding first wiring lines 142 and the first wiring contacts 146 are electrically connected to each other through the at least one wiring contact and the at least one wiring line.

A second inter-wiring insulating layer 148 is disposed between the first wire contacts 146. The second inter-wiring insulating layer 148 surrounds the first wiring contacts 146. The second inter-wiring insulating layer 148 includes silicon oxide or an insulating material with a lower dielectric constant than silicon oxide. For example, in some embodiments, the second inter-wiring insulating layer 148 includes at least one of a TEOS film, a ULK film, or an ELK film.

An isolation insulating layer 150 covers the first wiring contacts 146 and the second wiring insulating layer 148. The isolation insulating layer 150 includes an insulating material that has a higher dielectric constant than silicon oxide but a lower dielectric constant than silicon nitride. In some embodiments, the isolation insulating layer 150 includes an insulating material other than an oxide. For example, in an embodiment, the isolation insulating layer 150 include SiCN. The isolation insulating layer 150 covers the first wiring contacts 146 and the second wiring insulating layer 148 with a substantially constant thicknesses.

Lower electrode contacts 152 are disposed on corresponding first wiring contacts 146 in the first region. The lower electrode contacts 152 penetrate the isolation insulating layer 150 and contact the corresponding first wiring contacts 146. The lower electrode contacts 152 are formed when direct contact between the first wiring contact 146 and the variable resistance pattern structure 161 is challenging. For example, in some embodiments, when the first wiring contact 146 and the variable resistance pattern structure 161 are in direct contact with each other, the lower electrode contacts 152 are omitted.

A contact isolation insulating layer 154 covers a sidewall of the lower electrode contacts 152 on the isolation insulating layer 150 in the first region. An upper surface of a portion of the contact isolation insulating layer 154 disposed between adjacent lower electrode contacts 152 is located at a lower vertical level than the upper surface of the portion of the contact isolation insulating layer 154 that covers the sidewall of the lower electrode contacts 152. For example, the contact isolation insulating layer 154 conformally covers the upper surface of the isolation insulating layer 150 and the sidewall of the lower electrode contacts 152. The contact isolation insulating layer 154 includes silicon oxide. For example, the contact isolation insulating layer 154 includes a TEOS film.

The variable resistance pattern structure 161 of a memory cell is disposed on the lower electrode contact 152 in the first region. The variable resistance pattern structure 161 has an isolated island shape. A plurality of variable resistance pattern structures 161 are spaced apart from each other in the horizontal direction. A lower surface of the variable resistance pattern structure 161 contacts an upper surface of the lower electrode contact 152 and the upper surface of the portion of the contact isolation insulating layer 154 that covers the sidewall of the lower electrode contact 152. The variable resistance pattern structure 161 has a structure in which the lower electrode 160, the MTJ pattern 168, and the upper electrode 170 are stacked. For example, the lower surface of the lower electrode 160 contacts the upper surface of the lower electrode contact 152 and the upper surface of the portion of the contact isolation insulating layer 154 that covers the sidewall of the lower electrode contact 152.

The MTJ pattern 168 is a variable resistance layer and includes a pinned layer pattern 162, a tunnel barrier layer pattern 164, and a free layer pattern 166. The variable resistance pattern structure 161 has a tapered shape in which a horizontal width decreases away from the substrate 100 in the vertical direction (Z direction). For example, each of the lower electrode 160 in the variable resistance pattern structure 161, the MTJ pattern 168, which includes the pinned layer pattern 162, the tunnel barrier layer pattern 164, and the free layer pattern 166, and the upper electrode 170 have a tapered shape in which a horizontal width decreases away from the substrate 100 in the vertical direction (Z direction).

The lower electrode 160 and the upper electrode 170 each include a metal or a metal nitride. The pinned layer pattern 162 includes at least one of iron manganese (FeMn), iridium manganese (IrMn), platinum manganese (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), or chromium (Cr), etc.

A lower ferromagnetic layer, an antiferromagnetic coupling spacer layer, and an upper ferromagnetic layer may be further included on the pinned layer pattern 162. For example, each of the upper ferromagnetic layer and the lower ferromagnetic layer includes, for example, a ferromagnetic material that includes at least one of iron (Fe), nickel (Ni), or cobalt (Co). For example, the antiferromagnetic coupling spacer layer includes at least one of ruthenium (Ru), iridium (Ir), or rhodium (Rh). The tunnel barrier layer pattern 164 includes aluminum oxide or magnesium oxide. The free layer pattern 166 includes a ferromagnetic material that includes at least one of iron (Fe), nickel (Ni), or cobalt (Co).

Embodiments of the variable resistance pattern structure 161 are not necessarily limited to the configuration described above, and various modified embodiments are possible. In some embodiments, the variable resistance pattern structure 161 does not include the lower electrode 160.

A capping layer pattern 172 is formed on a sidewall of the variable resistance pattern structure 161 and a sidewall of the portion of the contact isolation insulating layer 154 that covers an upper sidewall portion of the lower electrode contact 152. The capping layer pattern 172 protects the variable resistance pattern structure 161. The capping layer pattern 172 includes an insulating material. For example, the capping layer pattern 172 includes silicon nitride.

Buried layer patterns 174 are formed on the capping layer pattern 172 and fill a part of spaces between the variable resistance pattern structures 161. The buried layer pattern 174 includes silicon oxide. For example, the buried layer pattern 174 includes silicon oxide formed through a high density plasma (HDP) process. The uppermost end of the buried layer pattern 174 is located at a lower vertical level than the uppermost end of the upper electrode 170, and the lowermost end of the buried layer pattern 174 is located at a higher vertical level than the upper surface of the isolation insulating layer 150.

A first insulating stopper layer 182 is formed on the capping layer pattern 172 and the buried layer pattern 174 in the first region. The first insulating stopper layer 182 fills the remaining part of the spaces between the variable resistance pattern structures 161 on the capping layer pattern 172. For example, lower portions of the spaces between the variable resistance pattern structures 161 on the capping layer pattern 172 are filled with the buried layer pattern 174, and upper parts thereof are filled with the first insulating stopper layer 182. The first insulating stopper layer 182 fills the upper portions of the spaces between the variable resistance pattern structures 161 on the capping layer pattern 172 and covers the uppermost surface of the capping layer pattern 172. The uppermost surface of the capping layer pattern 172 is located at a first vertical level LV1. A lower surface of a portion of the first insulating stopper layer 182 that covers the uppermost surface of the capping layer pattern 172 is located at the first vertical level LV1. In some embodiments, the uppermost end of the upper electrode 170 is located at the first vertical level LV1, but embodiments are not necessarily limited thereto. For example, in some embodiments, the uppermost end of the upper electrode 170 is located at a slightly lower vertical level than the first vertical level LV1. The uppermost end of the buried layer pattern 174 is located at a lower vertical level than the first vertical level LV1.

The first insulating stopper layer 182 further covers a sidewall of the capping layer pattern 172 that covers a sidewall of the outermost variable resistance pattern structure 161. For example, the first insulating stopper layer 182 further covers the sidewall of the capping layer pattern 172 that covers the sidewall that faces the second region of the variable resistance pattern structure 161 adjacent to the second region. A thickness of the portion of the first insulating stopper layer 182 that covers the sidewall of the capping layer pattern 172 that covers the sidewall of the variable resistance pattern structure 161 is greater than a thickness of a portion of the first insulating stopper layer 182 that covers the uppermost surface of the capping layer pattern 172. The thickness of the portion of the first insulating stopper layer 182 that covers the sidewall of the capping layer pattern 172 that covers the sidewall of the variable resistance pattern structure 161 is about 300 Å to about 400 Å.

The first insulating stopper layer 182 includes an insulating material that has a higher dielectric constant than silicon oxide but a lower dielectric constant than silicon nitride. In some embodiments, the first insulating stopper layer 182 includes an insulating material other than an oxide. For example, the first insulating stopper layer 182 includes SiCN.

The bit line 192B that extends while contacting the upper surfaces of the variable resistance pattern structures 161 is formed on the capping layer patterns 172, the buried layer patterns 174, and the variable resistance pattern structure 161. The bit line 192B contacts the upper electrode 170 of the variable resistance pattern structure 161. The bit line 192B has a structure in which a barrier metal layer and a metal layer are stacked. The barrier metal layer includes at least one of titanium, titanium nitride, tantalum, or tantalum nitride, etc. The metal layer includes at least one of copper, tungsten, or aluminum, etc. The bit line 192B extends in the second horizontal direction (Y direction). A plurality of bit lines 192B extend parallel to each other in the second horizontal direction (Y direction).

A third inter-wiring insulating layer 178 is formed on the isolation insulating layer 150 in the second region. At least a part of the third inter-wiring insulating layer 178 is located at the same vertical level as the buried layer pattern 174. The buried layer pattern 174 is located at the same vertical level as a portion of the third inter-wiring insulating layer 178. For example, the uppermost end of the third inter-wiring insulating layer 178 is located at a higher vertical level than the uppermost end of the buried layer pattern 174, and the lowermost end of the third inter-wiring insulating layer 178 is located at a lower vertical level than the lowermost end of the buried layer pattern 174. In some embodiments, the uppermost end of the third inter-wiring insulating layer 178 is located at the same vertical level as the uppermost end of the first insulating stopper layer 182, and the lowermost end of the third inter-wiring insulating layer 178 is located at the same vertical level as the upper surface of the isolation insulating layer 150. At least a part of the third inter-wiring insulating layer 178 is located at the same vertical level as the variable resistance pattern structure 161. The variable resistance pattern structure 161 is located at the same vertical level as the portion of the third inter-wiring insulating layer 178.

The third inter-wiring insulating layer 178 includes an insulating material with a lower dielectric constant than the buried layer pattern 174. For example, the third inter-wiring insulating layer 178 includes an insulating material with a lower dielectric constant than silicon oxide. In some embodiments, the third inter-wiring insulating layer 178 includes a ULK film or an ELK film.

A second insulating stopper layer 184 is formed in the second region and covers a part of the third inter-wiring insulating layer 178. The second insulating stopper layer 184 covers a part of the upper surface of the third inter-wiring insulating layer 178. A lower surface of the second insulating stopper layer 184 is located at a second vertical level LV2 that is higher than the first vertical level LV1. The upper surface of the first insulating stopper layer 182 and an upper surface of the second insulating stopper layer 184 are located at the same vertical level. The vertical level at which the upper surface of the first insulating stopper layer 182 and the upper surface of the second insulating stopper layer 184 are located may be referred to as a third vertical level. The third vertical level is higher than the first vertical level LV1 and the second vertical level LV2. The second insulating stopper layer 184 is spaced apart from the first insulating stopper layer 182 in the horizontal direction. The second insulating stopper layer 184 includes an insulating material that has a higher dielectric constant than silicon oxide but a lower dielectric constant than silicon nitride. In some embodiments, the second insulating stopper layer 184 includes an insulating material other than an oxide. For example, the second insulating stopper layer 184 includes SiCN. In some embodiments, the first insulating stopper layer 182 and the second insulating stopper layer 184 include the same material.

An insulating stopper recess 180R is defined between the second insulating stopper layer 184 and the first insulating stopper layer 182. The insulating stopper recess 180R between the second insulating stopper layer 184 and the first insulating stopper layer 182 is filled with the portion of the third inter-wiring insulating layer 178.

A second wiring line 192L and a second wiring contact 192C penetrate the second insulating stopper layer 184, the third inter-wiring insulating layer 178, and the isolation insulating layer 150, and are connected to the first wiring contact 146. For example, the second wiring line 192L penetrates the second insulating stopper layer 184 and an upper portion of the third inter-wiring insulating layer 178. The second wiring contact 192C is connected to the second wiring line 192L, penetrates a lower portion of the third inter-wiring insulating layer 178, penetrates the isolation insulating layer 150, and contacts the first wiring contact 146. The second wiring line 192L and the second wiring contact 192C include the same material as the bit line 192B. The second wiring line 192L and the second wiring contact 192C have a structure in which a barrier metal layer and a metal layer are stacked. The second wiring line 192L and the second wiring contact 192C that are connected to each other are integrally formed. In some embodiments, the upper surface of the first insulating stopper layer 182, an upper surface of the bit line 192B, an upper surface of the second wiring line 192L, the upper surface of the second insulating stopper layer 184, and the uppermost surface of the third inter-wiring insulating layer 178 are located at the same vertical level, that is, the third vertical level, and are coplanar.

An insulating cover layer 186 is formed on the first insulating stopper layer 182, the bit line 192B, the second wiring line 192L, the second insulating stopper layer 184, and the third inter-wiring insulating layer 178. The insulating cover layer 186 includes an insulating material that has a higher dielectric constant than silicon oxide but a lower dielectric constant than silicon nitride. In some embodiments, the insulating cover layer 186 includes an insulating material other than an oxide. For example, the insulating cover layer 186 includes SiCN. The first insulating stopper layer 182, the second insulating stopper layer 184, and the insulating cover layer 186 constitute an insulating stopper structure 180. In some embodiments, the first insulating stopper layer 182, the second insulating stopper layer 184, and the insulating cover layer 186 include the same material. The insulating stopper recess 180R is defined by the first insulating stopper layer 182, the second insulating stopper layer 184, and the insulating cover layer 186. The insulating stopper recess 180R extends from the lower surface of the insulating stopper structure 180 to the inside of the insulating stopper structure 180, but does not completely penetrate the insulating stopper structure 180. When the first insulating stopper layer 182 and the second insulating stopper layer 184 are together referred to as an insulating stopper layer, the insulating stopper recess 180R penetrates the insulating stopper layer, but does not extend into the insulating cover layer 186 and does not penetrate the insulating cover layer 186. The uppermost end of the insulating stopper recess 180R is located at the same vertical level as the upper surface of the first insulating stopper layer 182, the upper surface of the second insulating stopper layer 184, and the lower surface of the insulating cover layer 186.

A fourth inter-wiring insulating layer 194 is formed on the insulating cover layer 186. The fourth inter-wiring insulating layer 194 includes silicon oxide or an insulating material with a lower dielectric constant than silicon oxide. In some embodiments, the fourth inter-wiring insulating layer 194 includes at least one of a TEOS film, a ULK film, or an ELK film.

A third wiring line 198 and a third wiring contact 196 penetrate the fourth inter-wiring insulating layer 194 and the insulating cover layer 186 and are connected to the second wiring line 192L or the bit line 192B. For example, the third wiring line 198 penetrates an upper portion of the fourth inter-wiring insulating layer 194. The third wiring contact 196 is connected to the third wiring line 198, penetrate a lower portion of the fourth inter-wiring insulating layer 194, penetrate the insulating cover layer 186, and contacts the second wiring line 192L or the bit line 192B. The third wiring line 198 and the third wiring contact 196 each include the same or a similar material as the second wiring line 192L, the second wiring contact 192C, and the bit line 192B. The third wiring line 198 and the third wiring contact 196 have a structure in which a barrier metal layer and a metal layer are stacked. The third wiring line 198 and the third wiring contact 196 that are connected to each other are integrally formed. In some embodiments, the upper surface of the third wiring line 198 and the uppermost surface of the fourth inter-wiring insulating layer 194 may be located at the same vertical level and are coplanar.

The third inter-wiring insulating layer 178 has a first thickness T1. For example, the third inter-wiring insulating layer 178 has the first thickness T1 below the second insulating stopper layer 184. The insulating stopper recess 180R has a horizontal width WT. For example, a separation distance between the first insulating stopper layer 182 and the second insulating stopper layer 184 in the horizontal direction is the same as the horizontal width WT. The horizontal width WT is equal to or greater than the first thickness T1. The horizontal width WT is about 1 times to about 2 times the first thickness T1. For example, the first thickness T1 is about 1000 Å to about 2000Å. For example, the horizontal width WT is about 2000 Å to about 4000 Å.

The first insulating stopper layer 182 has a second thickness T2, and the second insulating stopper layer 184 has a third thickness T3. The third thickness T3 is less than the second thickness T2. The insulating cover layer 186 has a fourth thickness T4. The fourth thickness T4 is greater than each of the second thickness T2 and the third thickness T3. The sum of the second thickness T2 and the fourth thickness T4 and the sum of the third thickness T3 and the fourth thickness T4 are each about 180 Å to about 400 Å. Each of the second thickness T2, the third thickness T3, and the fourth thickness T4 is greater than about 50 Å.

In the variable resistance memory device VRM according to embodiments of the inventive concept, the buried layer pattern 174 fills the spaces between the relatively narrow variable resistance pattern structures 161 in the first region, and the third inter-wiring insulating layer 178 that surrounds the second wiring line 192L and the second wiring contact 192C fills the space that corresponds to the buried layer pattern 174 in the second region. The third inter-wiring insulating layer 178 includes an insulating material with a lower dielectric constant than the buried layer pattern 174, and the buried layer pattern 174 includes silicon oxide formed through an HDP process. Accordingly, the third inter-wiring insulating layer 178 minimizes the parasitic capacitance between the second wiring lines 192L and the second wiring contacts 192C, and the buried layer pattern 174 prevents voids from occurring in the spaces between the variable resistance pattern structures 161, and thus, the reliability of the variable resistance memory device VRM according to embodiments of the inventive concept is increased.

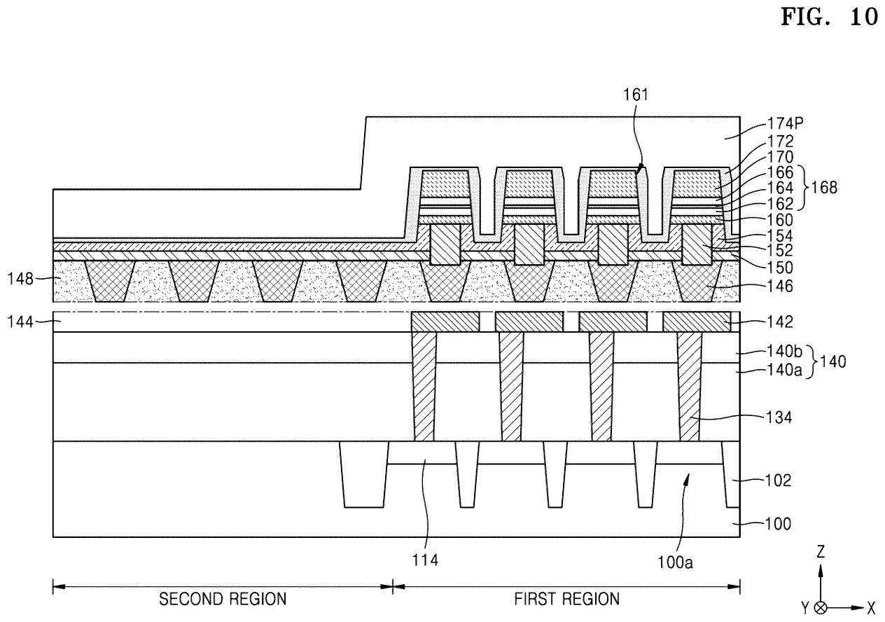

FIGS. 10 to 17 are cross-sectional views that illustrate a method of manufacturing a variable resistance memory device according to an embodiment. For example, FIGS. 10 to 17 are cross-sectional views taken along the line B-B′ in FIG. 7.

Referring to FIG. 10, in an embodiment, the first interlayer insulating layer 140 and the contact plugs 134 that penetrate the first interlayer insulating layer 140 are formed on the substrate 100, which includes the active regions 100a defined by the device isolation layer 102. Although not shown in FIG. 10, as shown in FIG. 8A, the first transistor 116 is formed in a first region, and the second transistor 118 is formed in a second region. The first wiring lines 142 that are electrically connected to the contact plugs 134 and the first inter-wiring insulating layer 144 that surround the first wiring lines 142 are disposed on the first interlayer insulating layer 140 and the contact plugs 134.

The second inter-wiring insulating layer 148 and the first wiring contact 146 that penetrates the second inter-wiring insulating layer 148 and is electrically connected to the first wiring lines 142 are formed on the first wiring lines 142 and the first inter-wiring insulating layer 144. The isolation insulating layer 150 that covers the first wiring contacts 146 and the second inter-wiring insulating layer 148 is formed, and the lower electrode contacts 152 that penetrate the isolation insulating layer 150 and contact the corresponding first wiring contacts 146, and the contact isolation insulating layer 154 that covers an upper surface of the isolation insulating layer 150 and sidewalls of the lower electrode contacts 152 are formed. The contact isolation insulating layer 154 is formed between two adjacent lower electrode contacts 152 and has a U-shaped vertical cross-section and the center of the contact isolation insulating layer 154 is concave.

The variable resistance pattern structure 161 is formed on the lower electrode contact 152 in the first region. A lower surface of the variable resistance pattern structure 161 contacts an upper surface of the lower electrode contact 152 and the upper surface of the portion of the contact isolation insulating layer 154 that covers the sidewall of the lower electrode contact 152. The variable resistance pattern structure 161 has a structure in which the lower electrode 160, the MTJ pattern 168, and the upper electrode 170 are stacked. The MTJ pattern 168 includes the pinned layer pattern 162, the tunnel barrier layer pattern 164, and the free layer pattern 166 and forms a variable resistance layer. The variable resistance pattern structure 161 has a tapered shape in which a horizontal width decreases away from the substrate 100 in the vertical direction (Z direction). For example, each of the lower electrode 160 in the variable resistance pattern structure 161, the MTJ pattern 168, which includes the pinned layer pattern 162, the tunnel barrier layer pattern 164, and the free layer pattern 166, and the upper electrode 170 has a tapered shape in which a horizontal width decreases away from the substrate 100 in the vertical direction (Z direction).

The capping layer pattern 172 is formed on the variable resistance pattern structure 161 and the contact isolation insulating layer 154, and a preliminary buried layer 174P that fills spaces between the variable resistance pattern structures 161 is formed on the capping layer pattern 172. The contact isolation insulating layer 154, the capping layer pattern 172, and the preliminary buried layer 174P are formed in the first region and the second region. The capping layer pattern 172 conformally covers the variable resistance pattern structure 161 and the contact isolation insulating layer 154. For example, the capping layer pattern 172 conformally covers a sidewall and an upper surface of the variable resistance pattern structure 161 and an upper surface and a sidewall of the contact isolation insulating layer 154. The preliminary buried layer 174P has a thickness that is sufficient to fill all of the spaces between the variable resistance pattern structures 161, and covers the variable resistance pattern structures 161. The preliminary buried layer 174P includes silicon oxide. The preliminary buried layer 174P is formed through an HDP process.

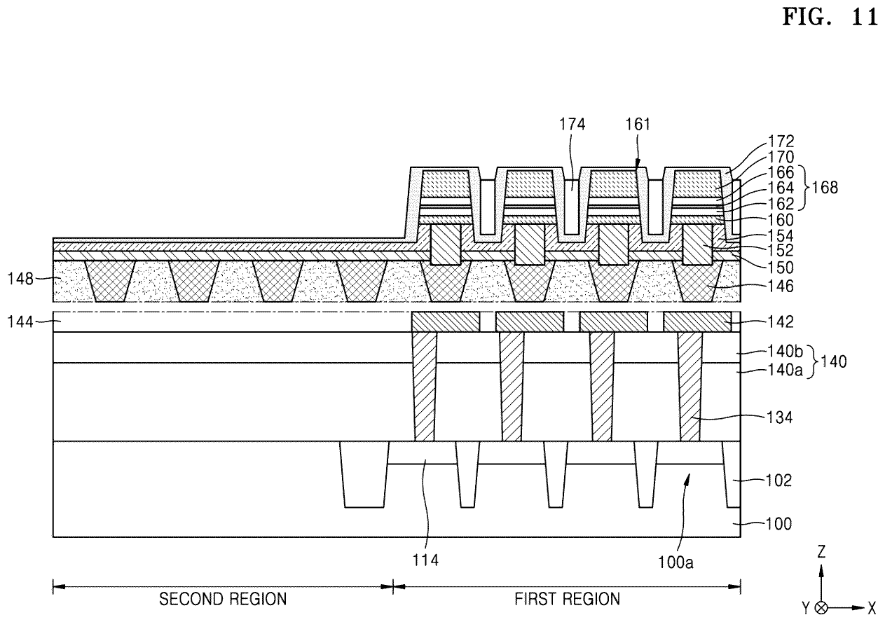

Referring to FIGS. 10 and 11 together, in an embodiment, the buried layer pattern 174 is formed by removing a part of the preliminary buried layer 174P. The buried layer patterns 174 is formed by removing a portion of the preliminary buried layer 174P that covers the second region, portions of the preliminary buried layer 174P that cover upper surfaces of the variable resistance pattern structures 161, and portions of the preliminary buried layer 174P that cover a part of upper portions of the spaces between the variable resistance pattern structures 161. The uppermost surface of the buried layer pattern 174 is located at a lower vertical level than the uppermost surface of the upper electrode 170. The buried layer patterns 174 are formed on the capping layer pattern 172 and fill lower portions of the spaces between the variable resistance pattern structures 161.

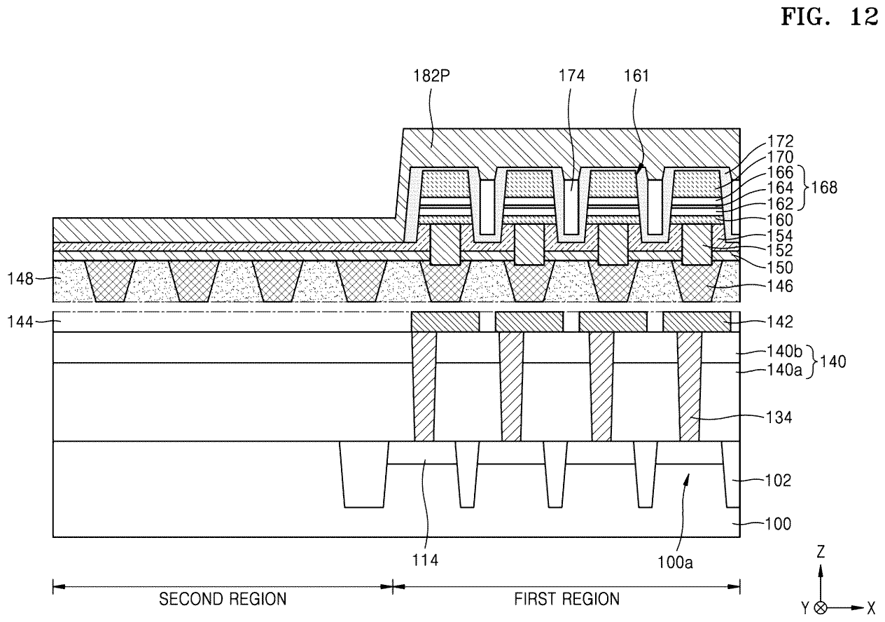

Referring to FIG. 12, in an embodiment, a first preliminary insulating stopper layer 182P is formed on the variable resistance pattern structures 161, the capping layer patterns 172, and the buried layer patterns 174. The first preliminary insulating stopper layer 182P is formed to a thickness that is sufficient to fill all spaces between the variable resistance pattern structures 161, and covers the variable resistance pattern structures 161. The first preliminary insulating stopper layer 182P includes an insulating material that has a higher dielectric constant than silicon oxide but a lower dielectric constant than silicon nitride. In some embodiments, the first preliminary insulating stopper layer 182P includes an insulating material other than an oxide. For example, the first preliminary insulating stopper layer 182P includes SiCN. The first preliminary insulating stopper layer 182P is formed in the first region and the second region.

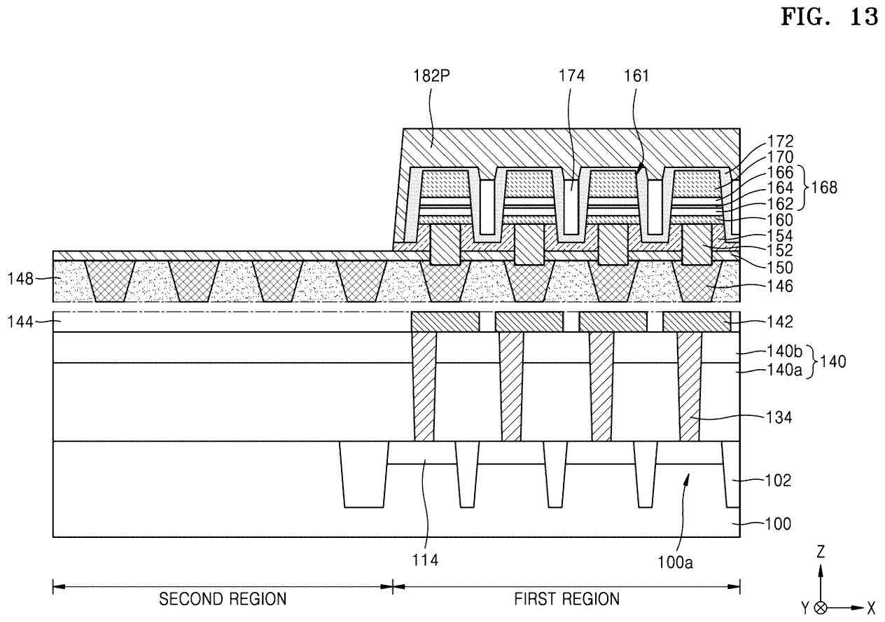

Referring to FIGS. 12 and 13, in an embodiment, a portion of the first preliminary insulating stopper layer 182P and a portion of the contact isolation insulating layer 154 formed in the second region are removed. The portion of the first preliminary insulating stopper layer 182P and the portion of the contact isolation insulating layer 154 are removed so that the upper surface of the isolation insulating layer 150 is exposed in the second region.

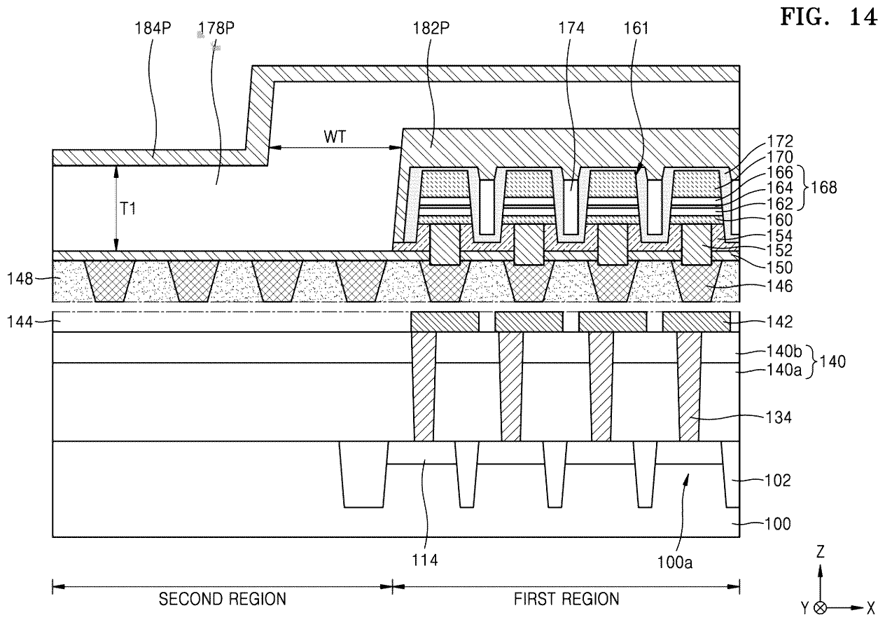

Referring to FIG. 14, in an embodiment, a preliminary inter-wiring insulating layer 178P and a second preliminary insulating stopper layer 184P are formed that cover the first preliminary insulating stopper layer 182P and the isolation insulating layer 150. The preliminary inter-wiring insulating layer 178P is formed such that an upper surface of a lowermost portion of the preliminary inter-wiring insulating layer 178P is located at a higher vertical level than the upper surface of the capping layer pattern 172. For example, the preliminary inter-wiring insulating layer 178P has at least the first thickness T1 in the second region. The second preliminary insulating stopper layer 184P and the first preliminary insulating stopper layer 182P are spaced apart from each other with the preliminary inter-wiring insulating layer 178P interposed therebetween. An upper portion of the first preliminary insulating stopper layer 182P is horizontally spaced apart from the second preliminary insulating stopper layer 184P by the horizontal width WT that is greater than the first thickness T1.

The preliminary inter-wiring insulating layer 178P includes an insulating material with a lower dielectric constant than the buried layer pattern 174. For example, the preliminary inter-wiring insulating layer 178P includes an insulating material with a lower dielectric constant than silicon oxide. In some embodiments, the preliminary inter-wiring insulating layer 178P includes a ULK film or an ELK film. The second preliminary insulating stopper layer 184P includes an insulating material that has a higher dielectric constant than silicon oxide but a lower dielectric constant than silicon nitride. In some embodiments, the second preliminary insulating stopper layer 184P includes an insulating material other than an oxide. For example, the second preliminary insulating stopper layer 184P includes SiCN. In some embodiments, the first preliminary insulating stopper layer 182P and the second preliminary insulating stopper layer 184P include the same material.

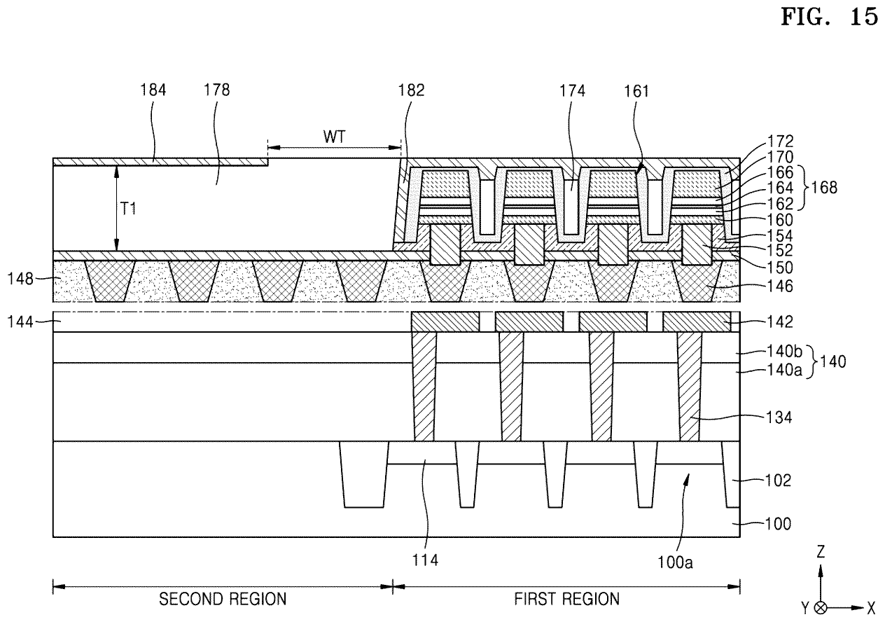

Referring to FIGS. 14 and 15 together, in an embodiment, the second insulating stopper layer 184, the third inter-wiring insulating layer 178, and the first insulating stopper layer 182 are formed by partially removing the upper portions of the second preliminary insulating stopper layer 184P, the preliminary inter-wiring insulating layer 178P, and the first preliminary insulating stopper layer 182P. The second insulating stopper layer 184, the third inter-wiring insulating layer 178, and the first insulating stopper layer 182 are formed by partially removing the upper portions of the second preliminary insulating stopper layer 184P, the preliminary inter-wiring insulating layer 178P, and the first preliminary insulating stopper layer 182P through a CMP planarization process. The upper surface of the first insulating stopper layer 182, the upper surface of the second insulating stopper layer 184, and the upper surface of the third inter-wiring insulating layer 178 are located at the same vertical level and are coplanar. On the upper surface of the capping layer pattern 172, the lower surface of the first insulating stopper layer 182 is located at the first vertical level LV1 shown in FIGS. 9A and 9B, and the lower surface of the second insulating stopper layer 184 is located at the second vertical level LV2 shown in FIGS. 9A and 9B. The second vertical level LV2 is higher than the first vertical level LV1.

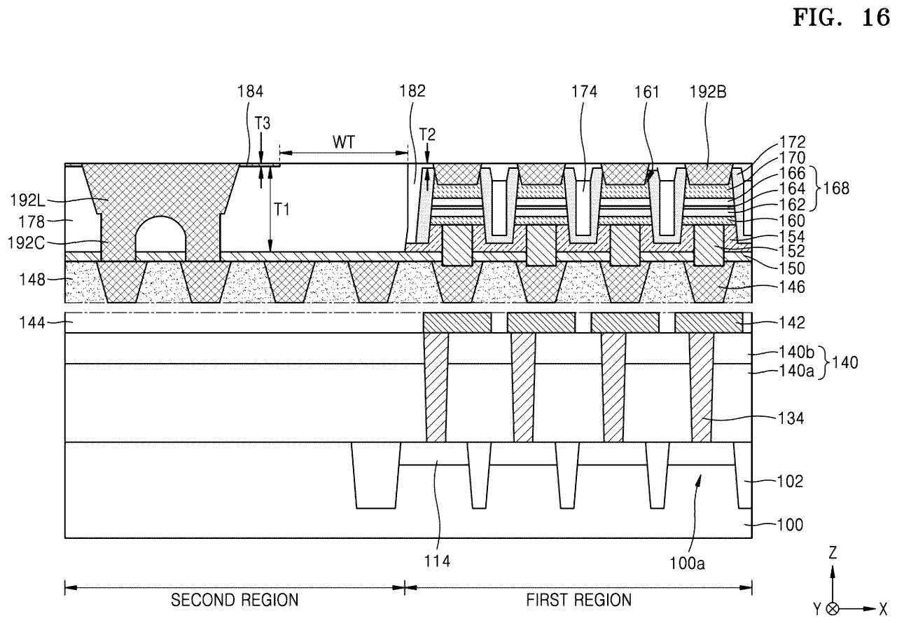

Referring to FIG. 16, in an embodiment, the bit lines 192B that extend while contacting the upper surfaces of the variable resistance pattern structures 161, and the second wiring line 192L and the second wiring contact 192C connected to the first wiring contact 146 are formed. The bit lines 192B penetrate the first insulating stopper layer 182 and contact the upper surfaces of the variable resistance pattern structures 161, such as the upper electrode 170. The second wiring line 192L and the second wiring contact 192C penetrate the second insulating stopper layer 184, the third inter-wiring insulating layer 178, and the isolation insulating layer 150 and are connected to the first wiring contact 146.

In some embodiments, the second wiring line 192L, the second wiring contact 192C, and the bit line 192B are formed together. For example, the second wiring line 192L, the second wiring contact 192C, and the bit line 192B are formed by removing a part of the first insulating stopper layer 182, a part of the second insulating stopper layer 184, a part of the third inter-wiring insulating layer 178, and a part of the isolation insulating layer 150, and filling, with a conductive material, spaces from which the part of the first insulating stopper layer 182, the part of the second insulating stopper layer 184, the part of the third inter-wiring insulating layer 178, and the part of the isolation insulating layer 150 are removed. In some embodiments, a part of the upper portion of the upper electrode 170 is removed when removing the part of the first insulating stopper layer 182, the part of the second insulating stopper layer 184, the part of the third inter-wiring insulating layer 178, and the part of the isolation insulating layer 150. In some embodiments, the bit lines 192B are formed to extend from the upper surface of the upper electrode 170 into the upper electrode 170.

The second wiring line 192L, the second wiring contact 192C, and the bit line 192B are formed by filling the spaces from which the part of the first insulating stopper layer 182, the part of the second insulating stopper layer 184, the part of the third inter-wiring insulating layer 178, and the part of the isolation insulating layer 150 are removed, forming a conductive material layer that covers the first insulating stopper layer 182, the second insulating stopper layer 184, and the third inter-wiring insulating layer 178, and removing a portion of the conductive material layer that covers the first insulating stopper layer 182, the second insulating stopper layer 184, and the third inter-wiring insulating layer 178 through a CMP process. In some embodiments, when forming the second wiring line 192L, the second wiring contact 192C, and the bit line 192B, a thickness of each of the first insulating stopper layer 182 and the second insulating stopper layer 184 is slightly reduced. The first insulating stopper layer 182 has the second thickness T2, and the second insulating stopper layer 184 has the third thickness T3. The third thickness T3 is less than the second thickness T2.

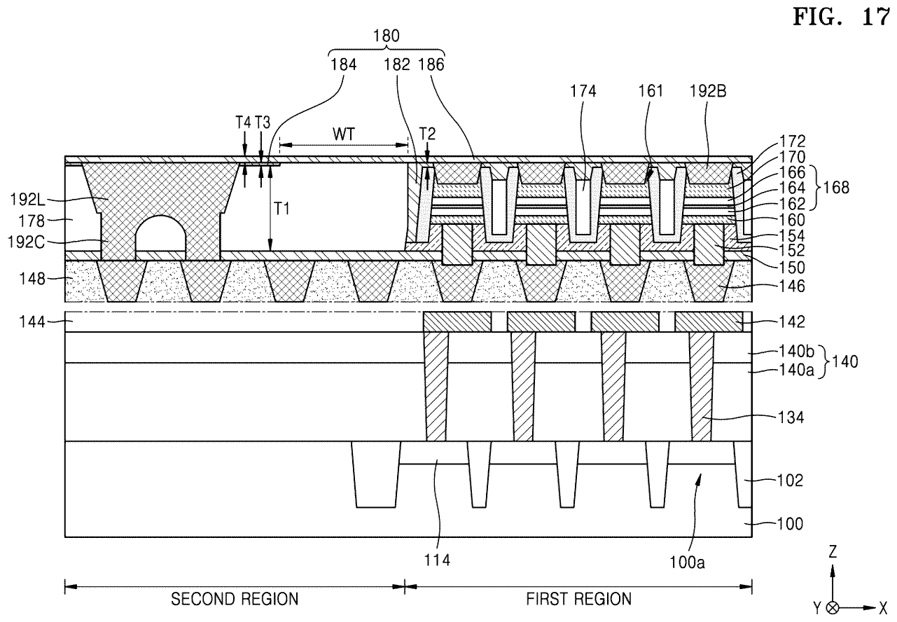

Referring to FIG. 17, in an embodiment, the insulating cover layer 186 is formed that covers the first insulating stopper layer 182, the second insulating stopper layer 184, and the third inter-wiring insulating layer 178. The insulating cover layer 186 is thicker than each of the first insulating stopper layer 182 and the second insulating stopper layer 184. For example, the insulating cover layer 186 has the fourth thickness T4 that is greater than each of the second thickness T2 and the third thickness T3.

Thereafter, the variable resistance memory device VRM can be formed by forming the fourth inter-wiring insulating layer 194, the third wiring line 198, and the third wiring contact 196 shown in FIGS. 9A and 9B.

Referring to FIGS. 10 to 17 together, in a method of manufacturing the variable resistance memory device VRM according to embodiments of the inventive concept, the spaces between the relatively narrow variable resistance pattern structures 161 in the first region are filled with the buried layer pattern 174, and the space that correspond to the buried layer pattern 174 in the second region are filled with the third inter-wiring insulating layer 178 that surrounds the second wiring line 192L and the second wiring contact 192C. The third inter-wiring insulating layer 178 minimizes the parasitic capacitance between the second wiring lines 192L and the second wiring contacts 192C, and the buried layer pattern 174 prevents voids from occurring in the spaces between the variable resistance pattern structures 161.

In addition, to form the third inter-wiring insulating layer 178, when removing a part of the preliminary inter-wiring insulating layer 178P, the first preliminary insulating stopper layer 182P in the first region and the second preliminary insulating stopper layer 184P in the second region each function as a stopper for the CMP planarization process. Therefore, a step between the first region and the second region can be minimized without performing a separate photolithography process, and a variable resistance memory device with increased reliability can be manufactured at a reduced manufacturing cost.

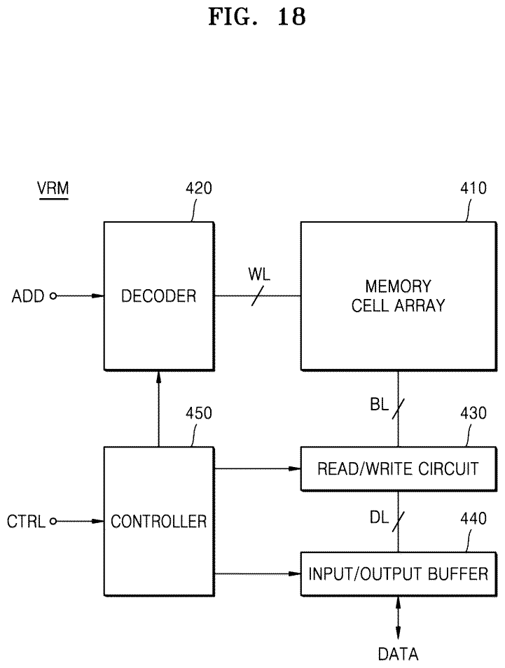

FIG. 18 is a block diagram of the variable resistance memory device VRM according to an embodiment.

Referring to FIG. 18, in an embodiment, the variable resistance memory device VRM according to an embodiment includes a memory cell array 410, a decoder 420, a read/write circuit 430, an input/output buffer 440, and a controller 450. The memory cell array 410 corresponds to the magnetoresistive memory cell array 80 of FIG. 1 and a first region of FIGS. 7A to 9B.

A plurality of memory cells in the memory cell array 410 are connected to the decoder 420 through word lines WL, and are connected to the read/write circuit 430 through bit lines BL. The decoder 420 receives an external address ADD and decodes a row address and a column address to be accessed in the memory cell array 410 under control of the controller 450 that operates according to a control signal CTRL.

The read/write circuit 430 receives data DATA from the input/output buffer 440 through a data line DL and writes the data DATA to a selected memory cell of the memory cell array 410 under control of the controller 450, or provides the data DATA read from the selected memory cell of the memory cell array 410 to the input/output buffer 440 under control of the controller 450. The memory cell include the variable resistance pattern structure 161 of FIGS. 7A to 9B.

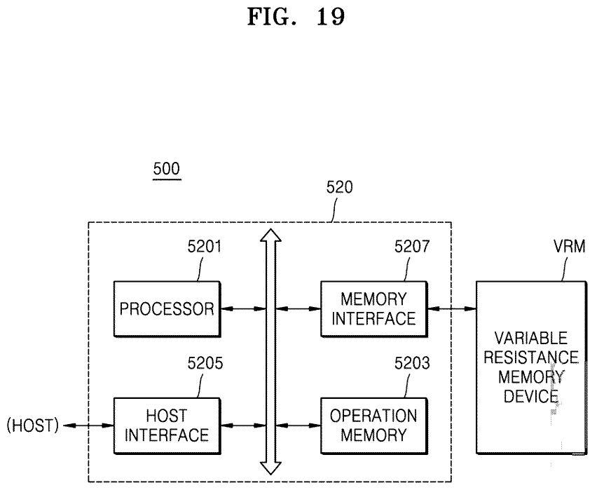

FIG. 19 is a block diagram of a data processing system 500 that includes the variable resistance memory device VRM according to an embodiment.

Referring to FIG. 19, in an embodiment, the data processing system 500 includes a memory controller 520 connected between a host and the variable resistance memory device VRM. The memory controller 520 can access the variable resistance memory device VRM in response to a request from the host. The memory controller 520 includes a processor 5201, an operation memory 5203, a host interface 5205, and a memory interface 5207.

The processor 5201 controls the overall operation of the memory controller 520, and the operation memory 5203 stores applications, data, control signals, etc., that are used by the memory controller 520. The host interface 5205 performs protocol conversion for data/control signal exchange between the host and the memory controller 520.

The memory interface 5207 performs protocol conversion for data/control signal exchange between the memory controller 520 and the variable resistance memory device VRM. The variable resistance memory device VRM is the same as that described above, and thus, a repeated description thereof is omitted. The data processing system 500 according to an embodiment may be a memory card, but is not necessarily limited thereto.

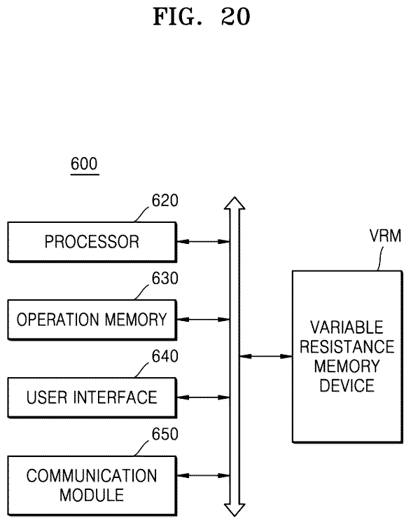

FIG. 20 is a block diagram of a data processing system 600 that includes the variable resistance memory device VRM according to an embodiment.

Referring to FIG. 20, in an embodiment, the data processing system 600 includes the variable resistance memory device VRM, a processor 620, an operation memory 630, and a user interface 640, and may further include a communication module 650 as necessary. The processor 620 is a central processing unit.

The operation memory 630 stores application programs, data, control signals, etc., used by the data processing system 600. The user interface 640 provides an environment in which a user may access the data processing system 600, and provides data processing results, etc., of the data processing system 600 to the user.

The variable resistance memory device VRM is substantially the same as that described above with reference to FIGS. 1 to 19, and thus, a repeated description thereof is omitted. The data processing system 600 may be a disk device, an internal/external memory card of a portable electronic device, or an image processor or other application chipsets.

While embodiments of the inventive concept have been particularly shown and described with reference to drawings thereof, it will be understood that various changes in form and details may be made therein without departing from the spirit and scope of the following claims.

What is claimed is:

1. A variable resistance memory device, comprising:
a substrate that includes a first region and a second region;
a plurality of variable resistance pattern structures disposed in the first region and that respectively constitute a plurality of memory cells and that are spaced apart from each other in a horizontal direction;
capping layer patterns that cover sidewalls of the plurality of variable resistance pattern structures;
an inter-wiring insulating layer disposed in the second region, wherein the inter-wiring insulating layer includes at least a part that is located at a same vertical level as the plurality of variable resistance pattern structures;
buried layer patterns disposed in the first region and that cover the capping layer patterns and fill a part of lower portions of spaces between the plurality of variable resistance pattern structures;
a first insulating stopper layer that fills a part of upper portions of the spaces between the plurality of variable resistance pattern structures and covers upper surfaces of the capping layer patterns;
a second insulating stopper layer disposed in the second region and that covers a part of an upper surface of the inter-wiring insulating layer and is spaced apart from the first insulating stopper layer in the horizontal direction; and
an insulating cover layer that covers an upper surface of the first insulating stopper layer, an upper surface of the second insulating stopper layer, and the upper surface of the inter-wiring insulating layer.

2. The variable resistance memory device of claim 1, wherein a separation distance between the first insulating stopper layer and the second insulating stopper layer in the horizontal direction is equal to or greater than a thickness of the inter-wiring insulating layer.

3. The variable resistance memory device of claim 2, wherein the separation distance between the first insulating stopper layer and the second insulating stopper layer in the horizontal direction is about 1 times to about 2 times the thickness of the inter-wiring insulating layer.

4. The variable resistance memory device of claim 1, wherein the upper surface of the first insulating stopper layer, the upper surface of the second insulating stopper layer, and an uppermost surface of the inter-wiring insulating layer are coplanar.

5. The variable resistance memory device of claim 4, wherein a thickness of the first insulating stopper layer is greater than a thickness of the second insulating stopper layer.

6. The variable resistance memory device of claim 5, wherein a thickness of the insulating cover layer is greater than the thickness of each of the first insulating stopper layer and the second insulating stopper layer.

7. The variable resistance memory device of claim 1, wherein a lower surface of the second insulating stopper layer is located at a higher vertical level than an uppermost surface of the capping layer patterns.

8. The variable resistance memory device of claim 1, wherein the inter-wiring insulating layer comprises an insulating material with a lower dielectric constant than each of the buried layer patterns.

9. The variable resistance memory device of claim 1, wherein each of the first insulating stopper layer, the second insulating stopper layer, and the insulating cover layer comprises an insulating material that has a higher dielectric constant than silicon oxide but a lower dielectric constant than silicon nitride.

10. The variable resistance memory device of claim 1, wherein
the first region comprises a cell array region, and
the second region comprises a peripheral circuit region.

11. A variable resistance memory device, comprising:
a substrate that includes a first region and a second region;
a plurality of variable resistance pattern structures disposed in the first region and that respectively constitute a plurality of memory cells and that are spaced apart from each other in a horizontal direction;
capping layer patterns that cover sidewalls of the plurality of variable resistance pattern structures;
buried layer patterns disposed in the first region and that cover the capping layer patterns and fill a part of lower portions of spaces between the plurality of variable resistance pattern structures;
an inter-wiring insulating layer disposed in the second region, wherein the inter-wiring insulating layer includes at least a part located at a same vertical level as the plurality of variable resistance pattern structures, and includes an insulating material with a lower dielectric constant than each of the buried layer patterns; and
an insulating stopper structure that fills a part of upper portions of the spaces between the plurality of variable resistance pattern structures and covers the capping layer patterns, the inter-wiring insulating layer, and the plurality of variable resistance patterns,
wherein the insulating stopper structure includes an insulating stopper recess located in a portion of the second region adjacent to the first region, extends from a lower surface of the insulating stopper structure to an inside of the insulating stopper structure, and is filled by a portion of the inter-wiring insulating layer.

12. The variable resistance memory device of claim 11, wherein a horizontal width of the insulating stopper recess in the horizontal direction is about 1 times to about 2 times a thickness of the inter-wiring insulating layer.

13. The variable resistance memory device of claim 11, wherein the insulating stopper structure comprises an insulating material that has a higher dielectric constant than silicon oxide but a lower dielectric constant than silicon nitride.

14. The variable resistance memory device of claim 11, wherein the insulating stopper structure includes:
a first insulating stopper layer that fills the part of the upper portions of the spaces between the plurality of variable resistance pattern structures and covers upper surfaces of the capping layer patterns in the first region;
a second insulating stopper layer that covers a part of an upper surface of the inter-wiring insulating layer in the second region; and
an insulating cover layer that covers an upper surface of the first insulating stopper layer, an upper surface of the second insulating stopper layer, and the upper surface of the inter-wiring insulating layer, and
the insulating stopper recess is defined by the first insulating stopper layer, the second insulating stopper layer, and the insulating cover layer.

15. The variable resistance memory device of claim 14, wherein the upper surface of the first insulating stopper layer, the upper surface of the second insulating stopper layer, and an upper surface of the portion of the inter-wiring insulating layer filling the insulating stopper recess are coplanar.

16. The variable resistance memory device of claim 15, wherein
a lower surface of the second insulating stopper layer is located at a higher vertical level than an uppermost surface of the capping layer patterns, and
a thickness of the first insulating stopper layer is greater than a thickness of the second insulating stopper layer.

17. The variable resistance memory device of claim 14, wherein a thickness of the insulating cover layer is greater than the thickness of each of the first insulating stopper layer and the second insulating stopper layer.

18. A variable resistance memory device, comprising:
a substrate that includes a cell array region and a peripheral circuit region;
an isolation insulating layer disposed in the cell array region and the peripheral circuit region;
a plurality of variable resistance pattern structures disposed on the isolation insulating layer in the cell array region, wherein the plurality of variable resistance pattern structures constitute a plurality of memory cells and are spaced apart from each other in a horizontal direction;
capping layer patterns that cover sidewalls of the plurality of variable resistance pattern structures and an upper surface of the isolation insulating layer;
buried layer patterns disposed in the cell array region and that cover the capping layer patterns and fill a part of lower portions of spaces between the plurality of variable resistance pattern structures;
an inter-wiring insulating layer disposed on the isolation insulating layer in the peripheral circuit region, wherein the inter-wiring insulating layer includes at least a part located at a same vertical level as the plurality of variable resistance pattern structures, and includes an insulating material with a lower dielectric constant than each of the buried layer patterns;
an insulating stopper structure that covers the capping layer patterns, the inter-wiring insulating layer, and the plurality of variable resistance patterns, and includes an insulating material that has a higher dielectric constant than silicon oxide but a lower dielectric constant than silicon nitride;
a bit line disposed in the cell array region and that penetrates the insulating stopper structure and extends in contact with upper surfaces of the plurality of variable resistance pattern structures; and
a wiring line and a wiring contact surrounded by the inter-wiring insulating layer,
wherein the insulating stopper structure includes
a first insulating stopper layer that fills a part of upper portions of the spaces between the plurality of variable resistance pattern structures and covers upper surfaces of the capping layer patterns in the cell array region,
a second insulating stopper layer that covers a part of an upper surface of the inter-wiring insulating layer and is spaced apart from the first insulating stopper layer in the horizontal direction in the peripheral circuit region,
an insulating cover layer that covers an upper surface of the first insulating stopper layer, an upper surface of the second insulating stopper layer, and the upper surface of the inter-wiring insulating layer, and
an insulating stopper recess defined by the first insulating stopper layer, the second insulating stopper layer, and the insulating cover layer, and that is filled by a portion of the inter-wiring insulating layer,
wherein a horizontal width of the insulating stopper recess in the horizontal direction is about 1 times to about 2 times a thickness of the inter-wiring insulating layer.

19. The variable resistance memory device of claim 18, wherein
the upper surface of the first insulating stopper layer, the upper surface of the second insulating stopper layer, and an upper surface of the portion of the inter-wiring insulating layer filling the insulating stopper recess are coplanar,
a lower surface of the second insulating stopper layer is located at a higher vertical level than an uppermost surface of the capping layer patterns,
a thickness of the first insulating stopper layer is greater than a thickness of the second insulating stopper layer, and
a thickness of the insulating cover layer is greater than the thickness of each of the first insulating stopper layer and the second insulating stopper layer.

20. The variable resistance memory device of claim 18, wherein the first insulating stopper layer, the second insulating stopper layer, and the insulating cover layer each include SiCN.
